(19) United States
(12) Patent Application Publication
(10) Pub. No.: US 2025/0029814 A1
(43) Pub. Date: Jan. 23, 2025

(54) FLEXIBLE MOUNTING CONNECTION STRUCTURE AND CORRESPONDING PLASMA PROCESSOR

(71) Applicant: ADVANCED MICRO-FABRICATION EQUIPMENT INC. CHINA, Shanghai (CN)

(72) Inventors: Mingming WANG, Shanghai (CN); Zhaoyang XU, Shanghai (CN)

(21) Appl. No.: 18/713,088

(22) PCT Filed: Sep. 15, 2022
(86) PCT No.: PCT/CN2022/119023

§ 371 Date: May 23, 2024

(30) Foreign Application Priority Data
Dec. 21, 2021 (CN) 202111571461.0

(51) Int. Cl. H01J 37/32

(52) U.S. Cl. CPC H01J 37/3244; H01J 2237/334

(57) ABSTRACT

The present disclosure provides a flexible mounting connection structure for connecting a first plate body and a second plate body with different coefficients of thermal expansion. The flexible mounting connection structure is provided with a thermal stress release portion, which is a structure capable of deforming, and is used for eliminating or reducing thermal stress caused by the different coefficients of thermal expansion of the first plate body and the second plate body during temperature changes through deformation to prevent the thermal stress from damaging the first plate body and the second plate body. Also provided in the present disclosure is a plasma processor employing the flexible mounting connection structure described above. The present disclosure protects the gas shower head and the mount base from being damaged by the thermal stress, and is large in displacement deformation, and thus the present disclosure can be applied to high-temperature etching processes.

### TECHNICAL FIELD

The present disclosure relates to the technical fields of plasma etching and thermal expansion, in particular to a flexible mounting connection structure and a corresponding plasma processor.

### BACKGROUND ART

Plasma processing is a common technology in the field of integrated circuits, and the processing steps are carried out inside a process chamber of a plasma processor. In a plasma processor applied by the present disclosure, an assembly body is disposed on a top of a process chamber, and the assembly body includes an aluminum mount base. A gas shower head made of ceramic (such as SiC or Si) is fixedly connected below the mount base by means of a connecting device, and used for introducing external process gas into the process chamber. During processing, it is necessary to apply a high radio-frequency power to the process gas introduced into the process chamber to generate plasma. This step will cause both the gas shower head and the mount base to rise to a higher temperature (higher than 100° C.), and then drop to the room temperature after the plasma processing is completed. Therefore, in frequent plasma processing technology, the temperature of the mount base and the gas shower head will frequently fluctuate back and forth. Currently, the connecting device between the mount base and the gas shower head is mostly a rigid connection structure, for example, a plurality of evenly distributed screws are generally employed for connecting and fixing. In the high-temperature environment, due to the different coefficients of thermal expansion of the mount base, the gas shower head and the rigid connection structure, some problems may arise:
for example, in such an environment with frequent temperature changes, it is easy to cause a larger gap or relative deformation between the mount base and the gas shower head, resulting in changes in the distribution of a radio-frequency electric field and heat in the entire plasma processor. These factors in turn will lead to changes in the plasma processing effect. Therefore, the rigid connection structure may lead to uneven and unstable processing effects of the entire plasma processor.

For another example, at the room temperature of 20° C., as the rigid connection structure, screws made of Hastlloy material with specifications M3×20 pass through the mount base made of an aluminum material to lock the gas shower head made of a ceramic material, where the coefficient of thermal expansion of Hastlloy CTE_{H}=10.5×10⁻⁶/K, the coefficient of thermal expansion of AL6061-T6 aluminum CTE_{AL}=24×10⁻⁶/K, and the calculation process of thermal expansion is as follows:
at 120° C., ΔL=120° C.-20° C=100° C.:
screw ΔL₁=20×100×10.5×10⁻⁶=0.021 mm;
base ΔL₂=20×100×24×10⁻⁶0.048 mm;
ΔL=ΔL₂−ΔL₁=0.027 mm;
Hastlloy elastic modulus E=213 GPa;
E=(F/A)/(ΔL/L), where F is an external force, A is a cross-sectional area of the screw, ΔL is a degree increment, and L is an original length;
F=EAΔL/L=213×10⁹×3.14×1.5²×10⁻⁶×0.027×10⁻³/(20×10⁻³)=2031.5 N

that is, when the torque is 30 cn*m at the room temperature, the preload is about 500 N; and when the temperature reaches 120° C., the expansion amount of 20 mm aluminum is 0.048 mm, the expansion amount of 20 mm Hastlloy is 0.021 mm, and then the screw will be elongated by ΔL=0.027 mm, so that the internal stress of the screw will increase by 2031.5 N. Especially in the case where the etching process requires a high temperature of the gas shower head, if the strength of the gas shower head is not enough, the gas shower head will be destroyed, so that a cracking phenomenon of the gas shower head is caused, and it is possible to damage the mount base.

### SUMMARY OF THE DISCLOSURE

An objective of the present disclosure is to provide a flexible mounting connection structure and a corresponding plasma processor. The present disclosure compensates for the difference values in thermal expansion between a mount base and a gas shower head which are made of different materials via the elastic deformation of the flexible mounting connection structure so as to protect the gas shower head and the mount base from being damaged by thermal stress, and is large in displacement deformation, and thus the present disclosure can be applied to high-temperature etching processes.

In order to achieve the above objective, the present disclosure is realized by the following technical solution:
a flexible mounting connection structure is used for connecting a first plate body and a second plate body with different coefficients of thermal expansion. The flexible mounting connection structure is provided with a thermal stress release portion; and the thermal stress release portion is a structure capable of deforming, and is used for eliminating or reducing thermal stress caused by the different coefficients of thermal expansion of the first plate body and the second plate body during temperature changes through deformation so as to prevent the thermal stress from damaging the first plate body and the second plate body.

Preferably, the thermal stress release portion includes:
a first release portion, including:
a plurality of petal-shaped pieces disposed at a bottom of the flexible mounting connection structure: and
a first deformation groove, formed in the bottom of the flexible mounting connection structure along a horizontal direction, bottoms of the petal-shaped pieces being separated by the first deformation groove, and the first deformation groove being used for providing a deformation space for the petal-shaped pieces.

Preferably, the thermal stress release portion further includes:
second release portions, which are second deformation grooves formed in inner wall surfaces of the petal-shaped pieces, a buffer hole being formed by the enclosure of the second deformation grooves, a bottom of the buffer hole being communicated with a top of the first deformation groove, and the buffer hole being used for providing the deformation space for the petal-shaped pieces and improving the elasticity of the petal-shaped pieces.

Preferably, the thermal stress release portion further includes:
third release portions, which are third deformation grooves formed in outer wall surfaces of the petal-shaped pieces along a horizontal direction, and are used for providing the deformation space for the petal-shaped pieces and improving the elasticity of the petal-shaped pieces.

Optionally, the flexible mounting connection structure is made of metal.

Preferably, the flexible mounting connection structure is made of stainless steel.

Optionally, the flexible mounting connection structure is a cylinder.

Optionally, the flexible mounting connection structure is formed by vertically connecting an upper connection assembly and a lower connection assembly, where
the upper connection assembly is fixed with the first plate body: and
the lower connection assembly is fixed with the second plate body, and the lower connection assembly is disposed under the upper connection assembly and is connected to the upper connection assembly.

Optionally, the thermal stress release portion is disposed at a bottom end of the lower connection assembly:

Optionally, second fixing portions protruding from the outer walls of the petal-shaped pieces are provided at bottom ends of the petal-shaped pieces of the thermal stress release portion;
the second plate body is correspondingly provided with second fixing slots with upward openings, the shapes and sizes of the second fixing slots are adapted to the second fixing portions of the petal-shaped pieces, and the diameters of rabbets of the second fixing slots are less than that of the bottoms of the entire petal-shaped pieces provided with the second fixing portions, thus preventing the bottoms of the petal-shaped pieces from becoming disconnected from the second fixing slots: and
the bottom end of the lower connection assembly is fixedly inserted into the second fixing slots by matching the second fixing portions with the second fixing slots.

Optionally, the two petal-shaped pieces and the one first deformation groove are available.

Optionally, top ends of the two petal-shaped pieces are not connected, a notch is reserved between the top ends of the two petal-shaped pieces, and the lower connection assembly further includes:
a connecting block, disposed in the notch between the two petal-shaped pieces, the shape and size of the connecting block being adapted to the notch; and
a connection positioning device, used for the connection and positioning between the two petal-shaped pieces and the connecting block.

Preferably, the notch is in a downward wedge shape, and the connecting block is a wedge block.

Optionally, the connection positioning device is composed of a through hole penetrating the two petal-shaped pieces and the connecting block, and a pin adapted to the through hole: and the connection and positioning between the two petal-shaped pieces and the connecting block are implemented by inserting the pin into the through hole.

Optionally, a top of the upper connection assembly is provided with a first fixing portion protruding from an outer wall of the upper connection assembly:
the first plate body is correspondingly provided with a first fixing slot, the shape and size of the first fixing slot are adapted to the first fixing portion of the upper connection assembly, a bottom of the first fixing slot is provided with a first through hole vertically penetrating the first plate body, and the diameter of the first through hole is adapted to the outer diameter of the upper connection assembly:
the upper connection assembly is fixed in the first plate body by matching the first fixing portion with the first fixing slot so as to prevent the top of the upper connection assembly from becoming disconnected from the first fixing slot: and
a connection slot with a downward opening is formed in a bottom end of the upper connection assembly, and the connection slot is sleeved outside the lower connection assembly.

Optionally, screw-thread fit structures which are adapted to each other are respectively disposed on an inner wall of the connection slot of the upper connection assembly and an outer wall of the lower connection assembly.

Preferably, there is a margin for the height of the connection slot such that a deformation space is provided between a top of the lower connection assembly and a top of the connection slot after the upper connection assembly and the lower connection assembly are screwed down so as to achieve the close fitting installation between the first plate body and the second plate body within an operating temperature range.

Optionally, the flexible mounting connection structure is used for a plasma processor: and the first plate body is a mount base in the plasma processor, and the second plate body is a gas shower head in the plasmon processor.

Preferably, a plurality of flexible mounting connection structures are evenly disposed along the horizontal direction of the mount base for connecting the mount base and the gas shower head.

A plasma processor includes a process chamber, the mount base disposed on a top of the process chamber, and a gas shower head disposed below the mount base, where the mount base and the gas shower head are connected and fixed by using the flexible mounting connection structure described above.

Compared with the prior art, the present disclosure has the advantages that:
1. the elastic deformation of the thermal stress release portion compensates for the difference values in thermal expansion between the gas shower head and the mount base which are made of different materials, which can allow the mount base and the gas shower head to be stably fixed, thus solving the problem that the gas shower head and the mount base may be damaged by the thermal stress under the condition of temperature changes, and achieving uniformity and stability in the processing effect of the plasma processor:
2. the present disclosure is a simple in structure and more convenient to install due to the split type design for the upper and lower connection assemblies, the wedge block design for the lower connection assembly, etc.: and
3. through the design of the first release portion, the second release portions and the third release portions, the present disclosure has the ability to release the thermal stress of displacement, contraction, stretching and torsion in all directions such as horizontal and vertical directions, and is large in displacement deformation so as to be capable of effectively releasing the high-temperature thermal stress, and thus the present disclosure can be applied to the high-temperature etching processes.

### BRIEF DESCRIPTION OF THE DRAWINGS

FIG. 1 is a schematic structural diagram of a plasma processing device:

FIG. 2 is a schematic structural diagram of a flexible mounting connection structure in an example provided by the present disclosure;

FIG. 3a is a front-view schematic structural diagram of a lower connection assembly in an example provided by the present disclosure; and

FIG. 3b is a side-view schematic structural diagram of the lower connection assembly in an example provided by the present disclosure.

### DETAILED DESCRIPTION OF THE DISCLOSURE

In order to make the objective, technical solution, and advantages of the present disclosure clearer, the present disclosure will be further described in combination with the accompanying drawings. The described examples should not be considered as limitations to the present disclosure. All other examples obtained by those of ordinary skill in the art without making creative efforts shall fall within the protection scope of the present disclosure.

In the following description, reference is made to “some examples”, “one or more examples”, which describes a subset of all possible examples, but it is to be understood that “some examples”, “one or more examples” may be the same subset or different subsets of all possible examples, and may be combined with each other without conflict.

In the following description, the term “first\second\third” is only used for distinguishing similar objects, and does not represent a specific order for the objects. It should be understood that “first\second\third” may be interchanged in a specific order or sequence when allowed, so that the examples of the present disclosure described herein can be implemented in an order other than that illustrated or described.

Unless otherwise defined, all technical and scientific terms used herein have the same meaning as commonly understood by those skilled in the art to which the present disclosure belongs. The terms used herein are only for the purpose of describing the examples of the present disclosure, and are not intended to limit the present disclosure.

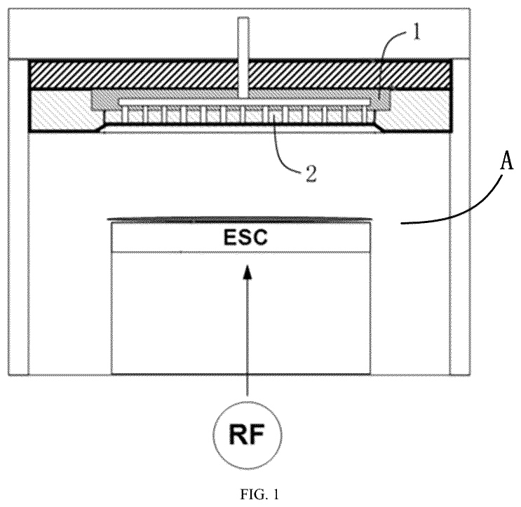

FIG. 1 shows a schematic diagram of a plasma processing device, including a process chamber A for processing a substrate: an aluminum mount base 1 is disposed on a top of the process chamber A, a gas shower head 2 made of ceramic is disposed under the mount base 1, and the gas shower head 2 is used for introducing external process gas into the process chamber A. In the prior art, the mount base 1 and the gas shower head 2 are fixed together to form an assembly body by means of a plurality of screws uniformly disposed in a horizontal direction. During the processing of the substrate, it is necessary to apply a high radio-frequency power to the process gas introduced into the process chamber A to generate plasma. This step will cause both the gas shower head 2 and the mount base 1 to rise to a higher temperature (higher than 100° C.), and then drop to the room temperature after the plasma processing is completed. Therefore, in frequent plasma processing technology; the temperature of the mount base 1 and the gas shower head 2 will frequently fluctuate back and forth. Due to the large difference value in the coefficient of thermal expansion between the aluminum mount base 1 and the ceramic gas shower head 2, when the temperature changes, on the one hand, the connecting screws will become loose, resulting in a larger gap or relative deformation between the mount base 1 and the gas shower head 2, which causes the distribution of a radio-frequency electric field and heat in the plasma processor to change, and further leads to uneven and unstable processing effects of the plasma processor: and on the other hand, especially in the high-temperature etching processes, the gas shower head 2 is subjected to an excessive pulling force, resulting in problems such as cracks, and the mount base I may be damaged even when reaching a certain temperature.

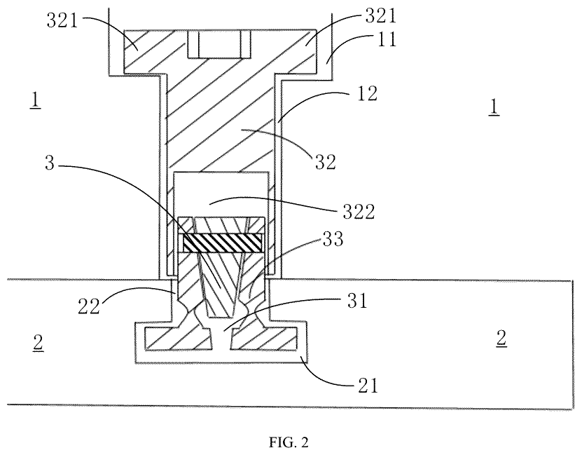

As shown in FIG. 2, the present disclosure provides a flexible mounting connection structure 3, with its top end fixed to a mount base 1 and its bottom end fixed to a gas shower head 2, which is used for replacing screws to fix the mount base 1 and the gas shower head 2 together, thereby solving the above technical problems. The working principle of the flexible mounting connection structure is that the flexible mounting connection structure 3 is provided with a thermal stress release portion 31, and the thermal stress release portion 31 is a structure capable of deforming. When the temperature changes, the thermal stress generated between the mount base 1 and the gas shower head 2 will be eliminated or reduced through the deformation of the thermal stress release portion 31, so that the mount base 1 and the gas shower head 2 are allowed to be well fitted to each other without a gap all the time: and furthermore, a pulling force on the gas shower head 2 and the mount base 1 is eliminated or reduced by the deformation, so that the gas shower head and the mount base are protected from being damaged.

In some examples, the flexible mounting connection structure 3 provided by the present disclosure is a cylinder, thus being easy for processing and not easy to produce particle pollutants because of the existence of edges and corners.

In some examples, the flexible mounting connection structure 3 provided by the present disclosure is made of metal, preferably stainless steel.

In some examples, the flexible mounting connection structure 3 provided by the present disclosure is an integral structure.

In some examples, the flexible mounting connection structure 3 provided by the present disclosure has a split type structure. FIG. 2 shows an assembled state diagram of one of the examples of the flexible mounting connection structure 3 employing the split type structure, and the flexible mounting connection structure includes an upper connection assembly 32, a top end of which is fixed to the mount base 1: and a lower connection assembly 33, a bottom end of which is fixed to the gas shower head 2, the lower connection assembly being disposed below the upper connection assembly 32 and connected to the upper connection assembly 32.

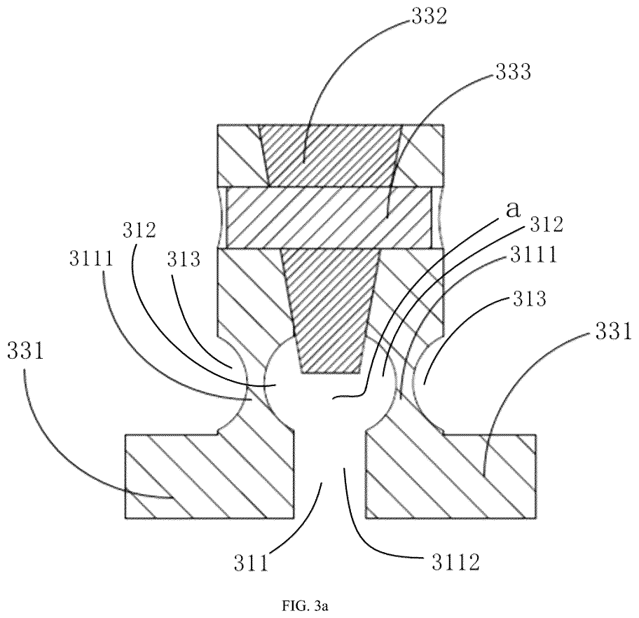

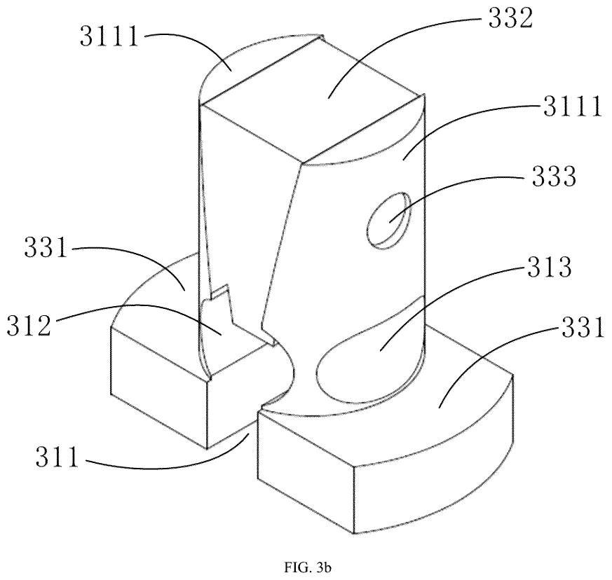

The thermal stress release portion 31 is disposed on the lower connection assembly 33: and in this example, as shown in FIG. 3a and FIG. 3b, the thermal stress release portion 31 is disposed at the bottom end of the lower connection assembly 33.

In some examples, the thermal stress release portion 31 includes a first release portion 311. The first release portion 311 includes a plurality of petal-shaped pieces 3111 disposed at a bottom of the flexible mounting connection structure 3, where each of the petal-shaped pieces 3111 may be in a straight strip shape or a structure with a curved or wavy profile: and a first deformation groove 3112, formed in a bottom of the lower connection assembly 33 along a horizontal direction, bottoms of the petal-shaped pieces 3111 being separated by the first deformation groove 3112, and the first deformation groove 3112 being used for providing a deformation space for the petal-shaped pieces 3111. In this example, the two petal-shaped pieces 3111 and the one first deformation groove 3112 are available.

In some examples, the thermal stress release portion 31 includes second release portions 312. The second release portions 312 are second deformation grooves formed in inner wall surfaces of the petal-shaped pieces 3111, a buffer hole “a” is formed by the enclosure of the second deformation grooves, a bottom of the buffer hole “a” is connected with a top of the first deformation groove 3112, and the buffer hole “a” is used for providing the deformation space for the petal-shaped pieces 3111 and improving the elasticity of the petal-shaped pieces 3111.

In some examples, the thermal stress release portion 31 includes third release portions 313. The third release portions 313 are third deformation grooves formed in outer wall surfaces of the petal-shaped pieces 3111 along a horizontal direction, and are used for providing the deformation space for the petal-shaped pieces 3111 and improving the elasticity of the petal-shaped pieces 3111.

In examples where the second release portions 312 and the third release portions 313 are both provided, it is possible to provide a greater deformation space and better elasticity for the petal-shaped pieces 3111.

In this example, the first release portion 311, the second release portions 312, and the third release portions 313 are all provided, so that the flexible mounting connection structure is better in thermal stress release capacity, has the ability to release the thermal stress of displacement, contraction, stretching and torsion in all directions such as horizontal and vertical directions, and is large in displacement deformation so as to be capable of effectively releasing the high-temperature thermal stress, and thus the flexible mounting connection structure can be applied to the high-temperature etching processes.

In addition to the listed first release portion 311, second release portions 312 and third release portions 313, the thermal stress release portion 31 may employ any structure or material that can deform at high temperatures to release thermal stress, or combinations of various structures and materials.

In this example, the connection relationship between the upper connection assembly 32 and the lower connection assembly 33 is achieved through the following structure: a connection slot 322 with a downward opening is formed in a bottom end of the upper connection assembly 32, and the connection slot 322 is sleeved outside the lower connection assembly 33: and further, screw-thread fit structures which are adapted to cach other are respectively disposed on an inner wall of the connection slot 322 of the upper connection assembly 32 and an outer wall of the lower connection assembly 33, and the upper connection assembly 32 is sleeved outside the lower connection assembly 33 by screw threads.

In order to ensure that the installation effect of the close fit between an upper surface of the gas shower head 2 and a lower surface of the mount base 1 at the room temperature is still maintained at a high temperature, preferably; after the upper connection assembly 32 and the lower connection assembly 33 are screwed down, an interstice is reserved between a top of the connection slot 322 and a top of the lower connection assembly 33 for serving as a deformation space between the upper connection assembly 32 and the lower connection assembly 33: and in this way, the upper connection assembly 32 and the lower connection assembly 33 can still maintain a tight connection state after deformation, so that the mount base 1 and the gas shower head 2 are not disconnected and excessively fitted to each other. That is, the fitting degree between the mount base 1 and the gas shower head 2 can be adjusted by adjusting the size of the interstice, which can adapt to different process application conditions and coordinate the tolerance existing after component processing.

In this example, the connection relationship between the upper connection assembly 32 and the mount base 1 is achieved through the following structure: a top of the upper connection assembly 32 is provided with a first fixing portion 321 protruding from an outer wall of the upper connection assembly: a first fixing slot 11 is formed at a corresponding position on the mount base 1, the shape and size of the first fixing slot 11 are adapted to the first fixing portion 321 of the upper connection assembly 32, a bottom of the first fixing slot 11 is provided with a first through hole 12 vertically penetrating the mount base 1, and the diameter of the first through hole 12 is adapted to the outer diameter of the upper connection assembly 32: and the upper connection assembly 32 is fixed in the mount base 1 by matching the first fixing portion 321 with the first fixing slot 11 so as to prevent the top of the upper connection assembly 32 from becoming disconnected from the first fixing slot 11.

In this example, the connection relationship between the lower connection assembly 33 and the gas shower head 2 is achieved through the following structure: second fixing portions 331 protruding from the outer walls of the petal-shaped pieces 3111 are provided at bottom ends of the petal-shaped pieces 3111 of the thermal stress release portion 31: the gas shower head 2 is correspondingly provided with second fixing slots 21 with upward openings, the shapes and sizes of the second fixing slots 21 are adapted to the second fixing portions 331 of the petal-shaped pieces 3111, and the diameters of rabbets of the second fixing slots 21 are less than that of the bottoms of the entire petal-shaped pieces 3111 provided with the second fixing portions 331, thus preventing the bottoms of the petal-shaped pieces 3111 from becoming disconnected from the second fixing slots 21: second through holes 22 are provided in the gas shower head 2 for communicating a top surface of the gas shower head 2 with the second fixing slots 21; and the bottom end of the lower connection assembly 33 is fixedly inserted into the second fixing slots 21 by matching the second fixing portions 331 with the second fixing slots 21, and a top end thereof is inserted into the second through holes 22.

In order to ensure that the installation effect of the close fit between the upper surface of the gas shower head 2 and the lower surface of the mount base 1 at the room temperature is still maintained at a high temperature, preferably, after the flexible mounting connection structure 3 is installed, interstices are reserved between a side wall of the flexible mounting connection structure 3 and a side wall of the first fixing slot 11, a side wall of the first through hole 12, side walls of the second through holes 22 as well as side walls of the second fixing slots 21, between the top of the flexible mounting connection structure 3 and the bottom of the first fixing slot 11, and between the bottom of the flexible mounting connection structure 3 and bottoms of the second fixing slots 21 for serving as deformation spaces between the flexible mounting connection structure 3 and the mount base 1 as well as between the flexible mounting connection structure and the gas shower head 2, thus reserving appropriate spaces for the deformation of the flexible mounting connection structure 3. After the deformation, the mount base 1 and the gas shower head 2 can still maintain their initial contact state with each other under the connection of the flexible mounting connection structure 3 without being disconnected or excessively fitted.

In order to realize that the bottom end of the lower connection assembly 33 can be inserted into the second fixing slots 21, in this example, the lower connection assembly 33 adopts the following split type structure design: top ends of the two petal-shaped pieces 3111 are not connected, a notch is reserved between the top ends of the two petal-shaped pieces, a connecting block 332 is disposed in the notch, and the shape and size of the connecting block 332 are adapted to the notch: preferably, the notch is in a downward wedge shape, and the connecting block 332 is an adaptive wedge block: and the downward wedge-shaped design can be adopted to facilitate installation, so as to prevent the connecting block 332 from falling from the notch to the bottoms of the second fixing slots 21 during installation.

When the connecting block 332 is installed in the notch, the connecting block 332 and the petal-shaped pieces 3111 on both sides need to be fixed by means of a connection positioning device 333. In this example, the connection positioning device 333 includes: a through hole penetrating the two petal-shaped pieces 3111 and the connecting block 332, and a pin adapted to the through hole: and the connection and positioning between the two petal-shaped pieces 3111 and the connecting block 332 are implemented by inserting the pin into the through hole.

According to the present disclosure, a plurality of flexible mounting connection structures 3 are evenly disposed along the horizontal direction of the mount base 1 for connecting and fixing the mount base 1 and the gas shower head 2.

An assembly method of the flexible mounting connection structures 3 in this example includes:

S1. connecting each of the upper connection assemblies 32 to the mount base 1: inserting the bottom end of each of the upper connection assemblies 32 into the first through hole 12 downward from the top of the mount base 1 to allow the first fixing portion 321 to be accommodated in the first fixing slot 11:

S2. connecting each of lower connection assemblies 33 to the gas shower head 2: successively inserting the second fixing portions 331 at the bottom ends of the two petal-shaped pieces 3111 into the second fixing slots 21 from the top of the gas shower head 2, then inserting the connecting block 332 into the notch between the two petal-shaped pieces 3111 downward in a wedge-like manner to allow the through hole to pass through the two petal-shaped pieces 3111 and the connecting block 332, and inserting the pin into the through hole to complete the positioning of the two petal-shaped pieces 3111 and the connecting block 332: and connecting each of the lower connection assemblies 33 to the gas shower head 2 according to the method as described above:

S3. connecting each of the upper connection assemblies 32 to each of the lower connection assemblies 33: aligning the mount base 1 with the gas shower head 2 up and down to align each of the upper connection assemblies 32 with each of the lower connection assemblies 33 one to one, and sleeving the connection slot 322 at the bottom end of one of the upper connection assemblies 32 onto the outside of the corresponding lower connection assembly 33 in a threaded manner and screwing down same appropriately: and connecting the other upper connection assemblies 32 to each of the lower connection assemblies 33 according to the above steps, then tightening the threads between each of the upper connection assemblies 32 and each of the lower connection assemblies 33 by using a diagonal fastening method, and assembling the mount base 1 and the gas shower head 2 into an assembly body through the connection of the flexible mounting connection structures 3; and

S4. connecting the assembly body to a plasma processor.

It should be noted that the flexible mounting connection structures 3 of the present disclosure are not limited to the application in the plasma processor, but can be applied to the connection between any components having different coefficients of thermal expansion.

In addition, this example provides a plasma processor, including a process chamber A, a mount base 1 disposed on a top of the process chamber A, a gas shower head 2 disposed below the mount base, and a plurality of flexible mounting connection structures 3 uniformly disposed along the horizontal direction of the mount base 1; and the mount base 1 and the gas shower head 2 are connected and fixed by means of each of the flexible mounting connection structures 3.

The above descriptions are merely examples of the present disclosure, and are not intended to limit the protection scope of the present disclosure. Any modification, equivalent replacement, improvement and the like made within the spirit and scope of the present disclosure are included in the protection scope of the present disclosure.

1. A flexible mounting connection structure, which is used for connecting a first plate body and a second plate body with different coefficients of thermal expansion, wherein the flexible mounting connection structure is provided with a thermal stress release portion; and
the thermal stress release portion is a structure capable of deforming, and is used for eliminating or reducing thermal stress caused by the different coefficients of thermal expansion of the first plate body and the second plate body during temperature changes through deformation so as to prevent the thermal stress from damaging the first plate body and the second plate body.

2. The flexible mounting connection structure according to claim 1, wherein the thermal stress release portion comprises:
a first release portion, comprising:
a plurality of petal-shaped pieces disposed at a bottom of the flexible mounting connection structure; and
a first deformation groove, formed in the bottom of the flexible mounting connection structure along a horizontal direction, bottoms of the petal-shaped pieces being separated by the first deformation groove, and the first deformation groove being used for providing a deformation space for the petal-shaped pieces.

3. The flexible mounting connection structure according to claim 2, wherein the thermal stress release portion further comprises:
second release portions, which are second deformation grooves formed in inner wall surfaces of the petal-shaped pieces, a buffer hole being formed by the enclosure of the second deformation grooves, a bottom of the buffer hole being communicated with a top of the first deformation groove, and the buffer hole being used for providing the deformation space for the petal-shaped pieces and improving the elasticity of the petal-shaped pieces.

4. The flexible mounting connection structure according to claim 2, wherein the thermal stress release portion further comprises:
third release portions, which are third deformation grooves formed in outer wall surfaces of the petal-shaped pieces along a horizontal direction, and are used for providing the deformation space for the petal-shaped pieces and improving the elasticity of the petal-shaped pieces.

5. The flexible mounting connection structure according to claim 1, wherein the flexible mounting connection structure is made of metal.

6. The flexible mounting connection structure according to claim 5, wherein the flexible mounting connection structure is made of stainless steel.

7. The flexible mounting connection structure according to claim 1, wherein the flexible mounting connection structure is a cylinder.

8. The flexible mounting connection structure according to claim 2, wherein the flexible mounting connection structure is formed by vertically connecting an upper connection assembly and a lower connection assembly, wherein
the upper connection assembly is fixed with the first plate body; and
the lower connection assembly is fixed with the second plate body, and the lower connection assembly is disposed under the upper connection assembly and is connected to the upper connection assembly.

9. The flexible mounting connection structure according to claim 8, wherein the thermal stress release portion is disposed at a bottom end of the lower connection assembly.

10. The flexible mounting connection structure according to claim 9, wherein second fixing portions protruding from the outer walls of the petal-shaped pieces are provided at bottom ends of the petal-shaped pieces of the thermal stress release portion;
the second plate body is correspondingly provided with second fixing slots with upward openings, the shapes and sizes of the second fixing slots are adapted to the second fixing portions of the petal-shaped pieces, and the diameters of rabbets of the second fixing slots are less than that of the bottoms of the entire petal-shaped pieces provided with the second fixing portions, thus preventing the bottoms of the petal-shaped pieces from becoming disconnected from the second fixing slots; and
the bottom end of the lower connection assembly is fixedly inserted into the second fixing slots by matching the second fixing portions with the second fixing slots.

11. The flexible mounting connection structure according to claim 10, wherein the two petal-shaped pieces and the one first deformation groove are available.

12. The flexible mounting connection structure according to claim 11, wherein top ends of the two petal-shaped pieces are not connected, a notch is reserved between the top ends of the two petal-shaped pieces, and the lower connection assembly further comprises:
a connecting block, disposed in the notch between the two petal-shaped pieces, the shape and size of the connecting block being adapted to the notch; and
a connection positioning device, used for the connection and positioning between the two petal-shaped pieces and the connecting block.

13. The flexible mounting connection structure according to claim 12, wherein the notch is in a downward wedge shape, and the connecting block is a wedge block.

14. The flexible mounting connection structure according to claim 13, wherein the connection positioning device is composed of a through hole penetrating the two petal-shaped pieces and the connecting block, and a pin adapted to the through hole; and the connection and positioning between the two petal-shaped pieces and the connecting block are implemented by inserting the pin into the through hole.

15. The flexible mounting connection structure according to claim 8, wherein a top of the upper connection assembly is provided with a first fixing portion protruding from an outer wall of the upper connection assembly;
the first plate body is correspondingly provided with a first fixing slot, the shape and size of the first fixing slot are adapted to the first fixing portion of the upper connection assembly, a bottom of the first fixing slot is provided with a first through hole vertically penetrating the first plate body, and the diameter of the first through hole is adapted to the outer diameter of the upper connection assembly;
the upper connection assembly is fixed in the first plate body by matching the first fixing portion with the first fixing slot so as to prevent the top of the upper connection assembly from becoming disconnected from the first fixing slot; and
a connection slot with a downward opening is formed in a bottom end of the upper connection assembly, and the connection slot is sleeved outside the lower connection assembly.

16. The flexible mounting connection structure according to claim 15, wherein screw-thread fit structures which are adapted to each other are respectively disposed on an inner wall of the connection slot of the upper connection assembly and an outer wall of the lower connection assembly.

17. The flexible mounting connection structure according to claim 16, wherein there is a margin for the height of the connection slot such that a deformation space is provided between a top of the lower connection assembly and a top of the connection slot after the upper connection assembly and the lower connection assembly are screwed down so as to achieve the close fitting installation between the first plate body and the second plate body within an operating temperature range.

18. The flexible mounting connection structure according to claim 1, wherein the flexible mounting connection structure is used for a plasma processor; and the first plate body is a mount base in the plasma processor, and the second plate body is a gas shower head in the plasmon processor.

19. The flexible mounting connection structure according to claim 18, wherein a plurality of flexible mounting connection structures are evenly disposed along the horizontal direction of the mount base for connecting the mount base and the gas shower head.

20. A plasma processor, comprising: a process chamber, a mount base disposed on a top of the process chamber, and a gas shower head disposed below the mount base, wherein the mount base and the gas shower head are connected and fixed by using the flexible mounting connection structures according to claim 19.

21. The flexible mounting connection structure according to claim 3, wherein the thermal stress release portion further comprises:
third release portions, which are third deformation grooves formed in outer wall surfaces of the petal-shaped pieces along a horizontal direction, and are used for providing the deformation space for the petal-shaped pieces and improving the elasticity of the petal-shaped pieces.
